(19) United States
(12) Patent Application Publication
(10) Pub. No.: US 2016/0035679 A1
(43) Pub. Date: Feb. 4, 2016

(54) DEVICES AND METHODS RELATED TO DUAL-SIDED RADIO-FREQUENCY PACKAGE HAVING SUBSTRATE CAVITY

(71) Applicant: SKYWORKS SOLUTIONS, INC., Woburn, MA (US)

(72) Inventors: Howard E. CHEN, Anaheim, CA (US); Anil K. AGARWAL, Ladera Ranch, CA (US); Robert Francis DARVEAUX, Gilbert, AZ (US); Sandra Louise PETTY-WEEKS, Newport Beach, CA (US); Amish Sudhir NAIK, Orange, CA (US); Robert H WILLIAMS, La Mirada, CA (US); Matthew Sean READ, Rancho Santa Margarita, CA (US)

(21) Appl. No.: 14/812,911

(22) Filed: Jul. 29, 2015

Related U.S. Application Data
(60) Provisional application No. 62/031,819, filed on Jul. 31, 2014.
(60) Provisional application No. 62/031,820, filed on Jul. 31, 2014.

(51) Int. Cl. H01L 23/552; H01L 23/498; H01L 23/538; H01L 21/52; H01L 25/16; H05K 1/18; H05K 1/02; H01L 23/66; H01L 23/31

(52) U.S. Cl. CPC H01L 23/552; H01L 23/66; H01L 23/49838; H01L 23/5389; H01L 23/3107; H01L 25/16; H05K 1/181; H05K 1/023; H01L 21/52

(57) ABSTRACT

Devices and method related to dual-sided radio-frequency package having substrate cavity. In some embodiment, a packaged RF device includes a packaging substrate configured to receive a plurality of components, the packaging substrate including a first side and a second side, the second side of the packaging substrate defining a pocket. The packaged RF device also includes a shielded package implemented on the first side of the packaging substrate, the shielded package including an RF circuit, the shielded package configured to provide RF shielding for at least a portion of the RF circuit. The packaged RF device further includes a component mounted substantially within the pocket of the second side of the packaging substrate.

### CROSS-REFERENCE TO RELATED APPLICATION(S)

This application claims priority to U.S. Provisional Patent Application No. 62/031,819 filed Jul. 31, 2014, entitled DEVICES AND METHODS RELATED TO SUPPORT FOR PACKAGING SUBSTRATE PANEL HAVING CAVITIES. This application also claims priority to U.S. Provisional Patent Application No. 62/031,820 filed Jul. 31, 2014, entitled DEVICES AND METHODS RELATED TO DUAL-SIDED RADIO-FREQUENCY PACKAGE HAVING SUBSTRATE CAVITY. The contents of each of the above-referenced application(s) are hereby expressly incorporated by reference herein in their entireties for all purposes.

### BACKGROUND

1. Field

The present disclosure relates to fabrication of packaged electronic modules such as radio-frequency (RF) modules

2. Description of the Related Art

In radio-frequency (RF) applications, RF circuits and related devices can be implemented in a packaged module. Such a packaged module can then be mounted on a circuit board such as a phone board

### SUMMARY

In some implementations, the present disclosure relates to a packaged radio-frequency (RF) device. The packaged RF device includes a packaging substrate configured to receive a plurality of components, the packaging substrate including a first side and a second side, the second side of the packaging substrate defining a pocket. The packaged RF device also includes a shielded package implemented on the first side of the packaging substrate, the shielded package including an RF circuit, the shielded package configured to provide RF shielding for at least a portion of the RF circuit. The packaged RF device further includes a component mounted substantially within the pocket of the second side of the packaging substrate.

In some embodiments, the first and second sides of the packaging substrate correspond to upper and lower sides, respectively, when the packaged RF device is oriented to be mounted on a circuit board.

In some embodiments, the pocket includes a mounting surface configured to allow the component to be mounted thereon.

In some embodiments, the mounting surface of the pocket is substantially parallel to the upper surface of the packaging substrate.

In some embodiments, the mounting surface of the pocket include a plurality of contact features configured to provide mounting and electrical connection functionalities for the component mounted thereon.

In some embodiments, the pocket has a box shape, the box shape having a depth that is greater than the height of the component mounted therein.

In some embodiments, the packaging substrate includes a perimeter surface that partially or fully surrounds the pocket, the perimeter surface configured to allow the packaged RF device to be mounted on a circuit board.

In some embodiments, the perimeter surface includes a plurality of contact pads.

In some embodiments, the packaging substrate includes a laminate substrate.

In some embodiments, the pocket is formed by an aperture in each of one or more lower-most layers of the laminate substrate.

In some embodiments, the packaging substrate includes a ceramic substrate.

In some embodiments, the ceramic substrate includes a low-temperature co-fired ceramic (LTCC) substrate.

In some embodiments, the shielded package includes an overmold structure that substantially encapsulates the RF circuit.

In some embodiments, the shielded package further includes an upper conductive layer implemented on the overmold structure, the upper conductive layer electrically connected to a ground plane within the packaging substrate.

In some embodiments, the electrical connection between the upper conductive layer and the ground plane is achieved through one or more conductors within the overmold structure.

In some embodiments, the one or more conductors include shielding wirebonds arranged relative to the RF circuit to provide RF shielding functionality for at least a portion of the RF circuit.

In some embodiments, the one or more conductors include one or more SMT devices mounted on the packaging substrate, the one or more SMT devices arranged relative to the RF circuit to provide RF shielding functionality for at least a portion of the RF circuit.

In some embodiments, the electrical connection between the upper conductive layer and the ground plane is achieved through a conformal conductive coating implemented on one or more sides of the overmold structure.

In some embodiments, the conformal conductive coating extends to corresponding one or more sides of the packaging substrate.

In some embodiments, the packaging substrate includes one or more conductive features each having a portion exposed at the corresponding side of the packaging substrate to form an electrical connection with the conformal conductive coating, each conductive feature further connected to the conductive plane within the substrate packaging.

In some embodiments, the upper conductive layer is a conformal conductive layer.

In some embodiments, the conformal conductive layer substantially covers all four sides of the overmold structure and all four sides of the packaging substrate.

In some embodiments, the component includes an SMT device.

In some embodiments, the SMT device includes a passive device or an active RF device.

In some embodiments, the component includes a die.

In some embodiments, the die includes a semiconductor die.

In some embodiments, the semiconductor die is configured to facilitate processing of RF signals by the RF circuit.

In some implementations, the present disclosure relates to a method for manufacturing packaged radio-frequency (RF) devices. The method includes providing or forming a packaging substrate configured to receive a plurality of components, the packaging substrate including a first side and a second side, the second side of the packaging substrate defining a pocket. The method also includes forming a shielded package on the first side of the packaging substrate, the shielded package including an RF circuit, the shielded package configured to provide RF shielding for at least a portion of the RF circuit. The method further includes mounting a component substantially within the pocket of the second side of the packaging substrate.

In some implementations, the present disclosure relates to a wireless device including a circuit board configured to receive a plurality of packaged modules. The wireless device also includes a shielded radio-frequency (RF) module mounted on the circuit board, the RF module including a packaging substrate configured to receive a plurality of components, the packaging substrate including a first side and a second side, the second side of the packaging substrate defining a pocket , the RF module further including a shielded package implemented on the first side of the packaging substrate, the shielded package including an RF circuit, the shielded package configured to provide RF shielding for at least a portion of the RF circuit, the RF module further including a component mounted substantially within the pocket of the second side of the packaging substrate.

### BRIEF DESCRIPTION OF THE DRAWINGS

FIG. 1 shows a dual-sided package having a shielded package and a lower component mounted thereto, according to some embodiments of the present disclosure.

FIG. 2 shows a shielded package with one or more lower components mounted under the shielded package, generally within a volume defined by an underside of the shielded package, according to some embodiments of the present disclosure.

FIG. 3 shows that a shielded package can be a wire-shielded package, according to some embodiments of the present disclosure.

FIG. 4 shows that in some embodiments, a shielded package can be a shielded package having a non-wire component that provides electrical connection between an upper conductive layer and a ground plane within a packaging substrate, according to some embodiments of the present disclosure.

FIG. 5 shows that in some embodiments, a shielded package can be a shielded package having a conformal conductive layer that is electrically connected to a ground plane within a packaging substrate, according to some embodiments of the present disclosure

FIGS. 6A and 6B show plan and perspective views of a shielded package without a lower component, according to some embodiments of the present disclosure.

FIGS. 7A and 7B show plan and perspective views of a shielded package with a lower component 104 mounted thereto, according to some embodiments of the present disclosure.

FIG. 8 shows a side sectional view of a layered packaging substrate such as a laminate substrate, according to some embodiments of the present disclosure.

FIG. 9 shows a side sectional view of an example dual-sided package that is similar to the example of FIG. 5, but showing additional example details in its packaging substrate portion of the shielded package, according to some embodiments of the present disclosure.

FIG. 10 shows that an under-fill can be provided between a lower component and an underside of a shielded package to which the lower component is mounted, according to some embodiments of the present disclosure.

FIG. 11 shows that a dual-sided package can include a plurality of lower components, according to some embodiments of the present disclosure.

FIGS. 12A-12D show various stages of a fabrication process in which substantially all of dual-sided features can be implemented in a panel format having an array of to-be-separated units, before such units are separated, according to some embodiments of the present disclosure.

FIGS. 13A-13D show various stages of a fabrication process in which a portion of the process is performed after individual units are singulated, according to some embodiments of the present disclosure.

FIG. 14 is a photograph of a side sectional view of a partially completed panel that includes a substrate and an overmold formed on the substrate, according to some embodiments of the present disclosure.

FIG. 15 is a photograph of a side sectional view of a partially completed panel that includes a substrate similar to the example of FIG. 14, according to some embodiments of the present disclosure.

FIG. 16 shows that a dual-sided package can include a shielded package having one or more surface-mount technology (SMT) devices mounted on a packaging substrate, according to some embodiments of the present disclosure.

FIG. 17 shows a dual-sided package that can be a more specific example of the dual-sided package of FIG. 16, according to some embodiments of the present disclosure.

FIG. 18 shows a dual-sided package that can be a more specific example of the dual-sided package of FIG. 17, according to some embodiments of the present disclosure.

FIG. 19 shows that in some embodiments, a dual-sided package having one or more features as described herein can be implemented as a diversity receive (RX) module 100, according to some embodiments of the present disclosure.

FIG. 20 shows that in some embodiment a dual-sided package having one or more features as described herein can be implemented in other types of LNA applications, according to some embodiments of the present disclosure.

### DESCRIPTION OF SOME EMBODIMENTS

The headings provided herein, if any, are for convenience only and do not necessarily affect the scope or meaning of the claimed invention.

### Introduction

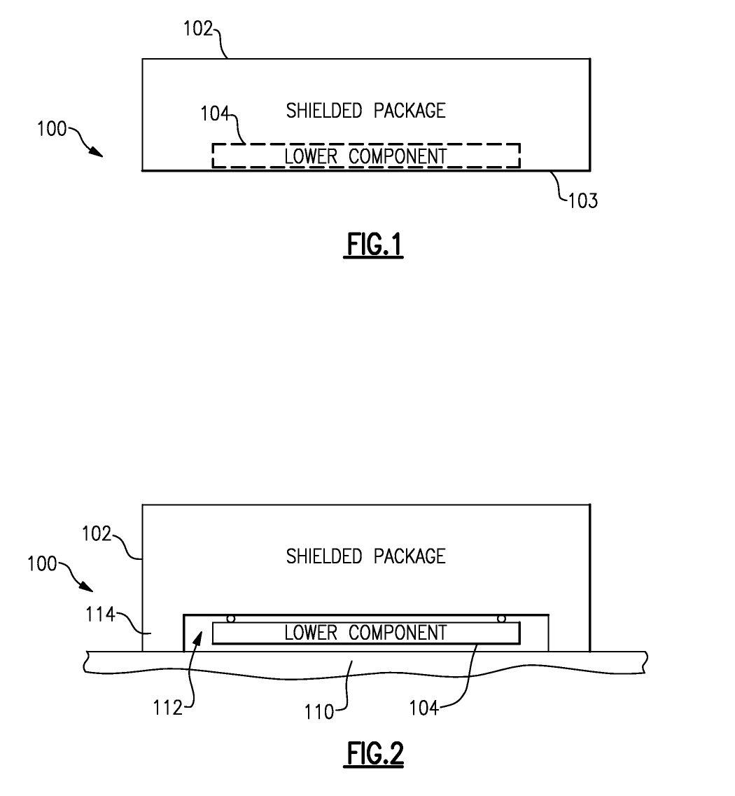

FIG. 1 shows a dual-sided package 100 having a shielded package 102 and a lower component 104 mounted thereto. For the purpose of description, a lower side of the shielded package 102 can include a side 103 of a packaging substrate that is to be mounted onto a circuit board such as a phone board. Although not shown separately in FIG. 1, it will be understood that the shielded package 102 can include such a packaging substrate and one or more upper components mounted on its upper side (when oriented as shown in FIG. 1). Accordingly, the dual-side property can include such upper component(s) mounted over the substrate and lower component(s) mounted in one or more cavities defined on the lower side 103 of the substrate. Examples of such cavities (also referred to as pockets herein) are described herein in greater detail.

For the purpose of description, it will be understood that a lower component can include any device that can be mounted on the substrate and/or the circuit board. Such a device can be an active radio-frequency (RF) device or a passive device that facilitates processing of RF signals. By way of non-limiting examples, such a device can include a die such as a semiconductor die, an integrated passive device (IPD), a surface-mount technology (SMT) device, and the like. In some embodiments, the lower component as described herein can be electrically coupled to the one or more upper component through, for example, the substrate.

FIG. 2 shows that in some embodiments, one or more lower components can be mounted under a shielded package, generally within a volume defined by an underside of the shielded package. In FIG. 2, a volume 112 under a shielded package 102 is shown to be defined by a pocket formed on the underside of the shielded package 102. Such a pocket can be defined by a recess on the underside of the shielded package 102, with one or more structures to allow mounting of the shielded package 102 on a circuit board 110 such as a phone board. In the example shown in FIG. 2, the pocket is depicted as being formed generally in the middle portion of the shielded package 102, such that four walls 114 surround the lateral sides of the volume 112 and allow mounting of the shielded package 102. In some embodiments, the one or more structures such as the four walls 114 can be integral part of the shielded package 102 (e.g., pocket can be formed on the underside of a substrate), be added on to the shielded package 102, or any combination thereof. The one or more structures such as the four walls 114 can be configured so that when mounted to the circuit board 110, there is sufficient vertical space between the upper surface of the circuit board 110 and the inner surface of the pocket for the lower component 104. Examples related to fabrication of dual-sided packages having such a configuration are described herein in greater detail.

Examples of Dual-Sided Packages with Underside Pocket

FIGS. 3-5 show non-limiting examples of dual-sided packages having underside pockets. More particularly, FIGS. 3-5 show examples of configurations of shielded packages that can be utilized.

FIG. 3 shows that in some embodiments, the shielded package 102 of FIG. 2 can be a wire-shielded package 200. The wire-shielded package 200 is shown to include a packaging substrate 202 (e.g., a laminate substrate) and a plurality of components mounted thereon. For example, a first component 124 is depicted as being mounted on the upper surface of the packaging substrate 202, and electrical connections between the component 124 and the packaging substrate 202 can be facilitated by, for example, wirebonds 128. In another example, a second component 126 is shown to be mounted on the upper surface of the packaging substrate 202 in a die-attach configuration. Electrical connections between the component 126 and the packaging substrate 202 can be facilitated by, for example, die-attach features.

In the example of FIG. 3, a plurality of shielding wires 130 (e.g. shielding wirebonds) are shown to be provided over the packaging substrate 202. Such shielding wires 130 can be electrically connected to a ground plane (not shown) within the packaging substrate 202. The shielding wires 130 as well as the mounted components 124, 126 are shown to be encapsulated by an overmold 132. The upper surface of the overmold 132 can be configured to expose the upper portions of the shielding wires 130, and an upper conductive layer 134 can be formed thereon. Accordingly, a combination of the upper conductive layer 134, the shielding wires 130, and the ground plane can define a shielded volume or region. Such a configuration can be implemented to provide shielding functionality between regions within and outside of the shielded package 200, and/or between regions that are both within the shielded package 200. Additional details concerning such shielding can be found in, for example, U.S. Pat. No. 8,373,264 entitled SEMICONDUCTOR PACKAGE WITH INTEGRATED INTERFERENCE SHIELDING AND METHOD OF MANUFACTURE THEREOF which is expressly incorporated by reference in its entirety.

In the example of FIG. 3, the underside of the packaging substrate 202 is shown to include an underside pocket 204, and a lower component 104 is shown to be mounted therein to thereby form a dual-sided package 100. The portion of the packaging substrate 202 surrounding the pocket 204 is shown to be configured to allow mounting of the dual-sided package 100. For example, the dual-sided package 100 is shown to be mounted on a circuit board 110 such as a phone board with contact pads 206.

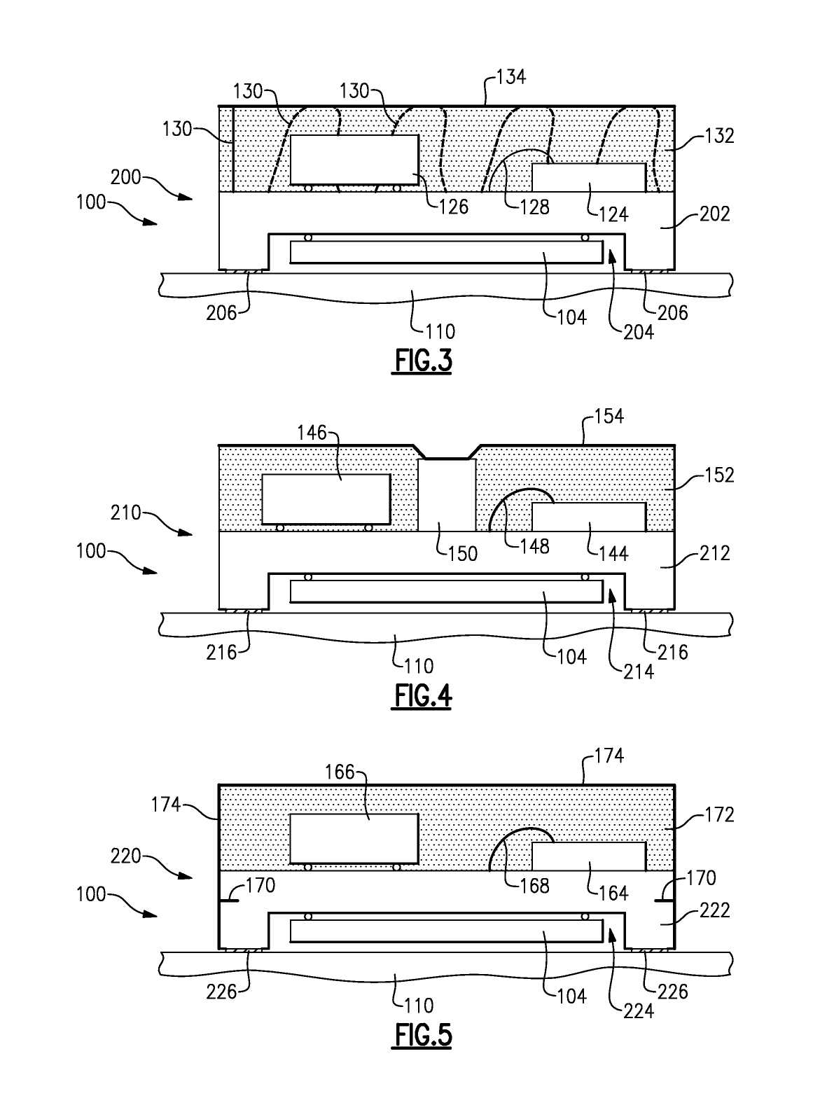

FIG. 4 shows that in some embodiments, the shielded package 102 of FIG. 2 can be a shielded package 210 having a non-wire component 150 that provides electrical connection between an upper conductive layer 154 and a ground plane (not shown) within a packaging substrate 212 (e.g., a laminate substrate). In addition to the component 150, the packaging substrate 212 is shown to have a plurality of components mounted thereon. For example, a first component 144 is depicted as being mounted on the upper surface of the packaging substrate 212, and electrical connections between the component 144 and the packaging substrate 212 can be facilitated by, for example, wirebonds 148. In another example, a second component 146 is shown to be mounted on the upper surface of the packaging substrate 212 in a die-attach configuration. Electrical connections between the component 146 and the packaging substrate 212 can be facilitated by, for example, die-attach features.

In the example of FIG. 4, the component 150 is shown to provide an electrical connection between the upper conductive layer 154 and the ground plane (not shown) within the packaging substrate 212. The component 150 as well as the mounted components 144, 146 are shown to be encapsulated by an overmold 152. The upper surface of the overmold 152 can be configured to expose the upper portion of the component 150, and the upper conductive layer 154 can cover such an exposed portion as well as the remaining upper surface of the overmold 152. Accordingly, a combination of the upper conductive layer 154, the component 150, and the ground plane can define a shielded volume or region. Such a configuration can be implemented to provide shielding functionality between regions within and outside of the shielded package 210, and/or between regions that are both within the shielded package 210. Additional details concerning such shielding can be found in, for example, U.S. patent application Ser. No. 14/252,719 filed on Apr. 14, 2014, entitled APPARATUS AND METHODS RELATED TO CONFORMAL COATING IMPLEMENTED WITH SURFACE MOUNT DEVICES, which is expressly incorporated by reference in its entirety.

In the example of FIG. 4, the underside of the packaging substrate 212 is shown to include an underside pocket 214, and a lower component 104 is shown to be mounted therein to thereby form a dual-sided package 100. The portion of the packaging substrate 212 surrounding the pocket 214 is shown to be configured to allow mounting of the dual-sided package 100. For example, the dual-sided package 100 is shown to be mounted on a circuit board 110 such as a phone board with contact pads 216.

FIG. 5 shows that in some embodiments, the shielded package 102 of FIG. 2 can be a shielded package 220 having a conformal conductive layer 174 that is electrically connected to a ground plane (not shown) within a packaging substrate 222 (e.g., a laminate substrate or a ceramic substrate). The shielded package 220 is shown to include a plurality of components mounted on the packaging substrate 222. For example, a first component 164 is depicted as being mounted on the upper surface of the packaging substrate 222, and electrical connections between the component 164 and the packaging substrate 222 can be facilitated by, for example, wirebonds 168. In another example, a second component 166 is shown to be mounted on the upper surface of the packaging substrate 222 in a die-attach configuration. Electrical connections between the component 166 and the packaging substrate 222 can be facilitated by, for example, die-attach features.

In the example of FIG. 5, the mounted components 164, 166 are shown to be encapsulated by an overmold 172. The conformal conductive layer 174 is shown to generally cover the upper surface of the overmold 172, as well as side walls (e.g., all four side walls) defined by the sides of the overmold 172 and the packaging substrate 222. The packaging substrate 222 is shown to include conductive features 170 having portions exposed on the sides of the packaging substrate, and also electrically connected to the ground plane (not shown), to thereby provide electrical connections between the conformal conductive layer 174 and the ground plane. Accordingly, a combination of the conformal conductive layer 174 and the ground plane can define a shielded volume or region. Such a configuration can be implemented to provide shielding functionality on one or more sides of the shielded package 220. Additional details concerning such shielding can be found in, for example, U.S. patent application Ser. No. 14/528,447 filed on Oct. 30, 2014, entitled DEVICES AND METHODS RELATED TO PACKAGING OF RADIO-FREQUENCY DEVICES ON CERAMIC SUBSTRATES, which is also expressly incorporated by reference in its entirety for all purposes.

In the example of FIG. 5, the underside of the packaging substrate 222 is shown to include an underside pocket 224, and a lower component 104 is shown to be mounted therein to thereby form a dual-sided package 100. The portion of the packaging substrate 222 surrounding the pocket 224 is shown to be configured to allow mounting of the dual-sided package 100. For example, the dual-sided package 100 is shown to be mounted on a circuit board 110 such as a phone board with contact pads 226.

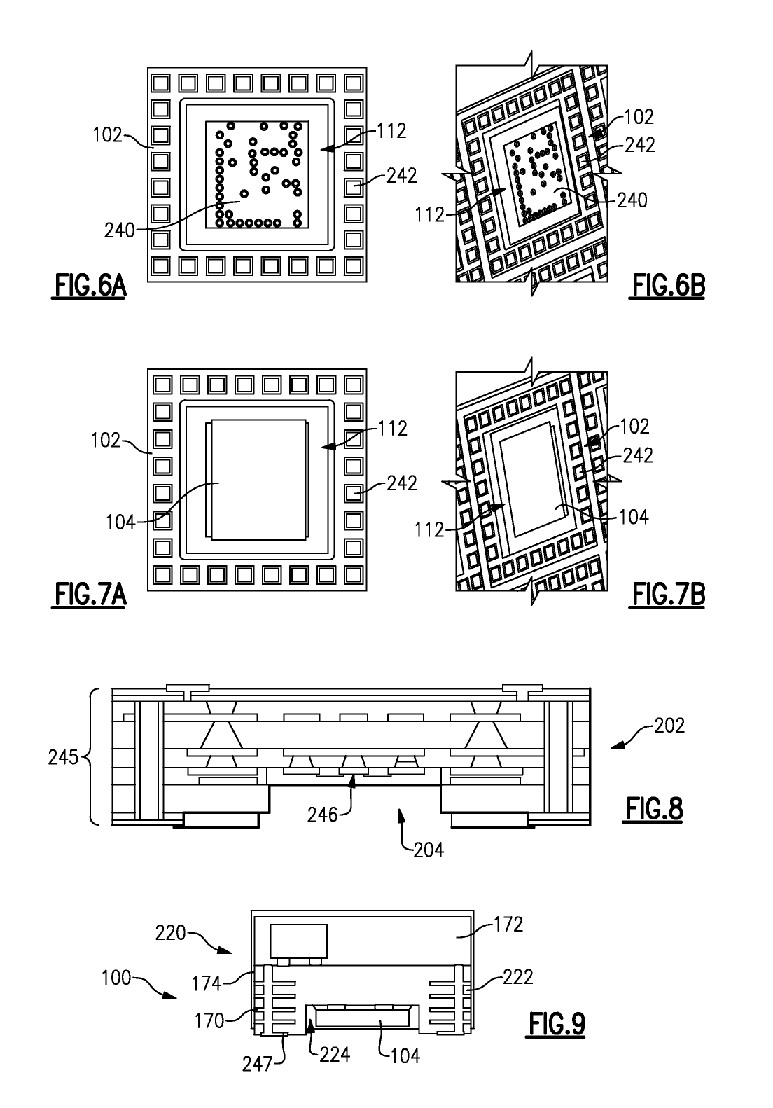

FIGS. 6 and 7 show an example configuration of an underside of a shielded package 102 such as the shielded package of FIG. 2. FIGS. 6A and 6B show plan and perspective views of the shielded package 102 without a lower component. FIGS. 7A and 7B show plan and perspective views of the shielded package 102 with a lower component 104 mounted thereto.

As shown in FIGS. 6A and 6B, the underside of the shielded package 102 can include a pocket 112 dimensioned to receive the lower component (104 in FIGS. 7A and 7B). As described herein, such a lower component can be, for example, a die having a plurality of contact pads. A mounting area indicated as 240 is shown to include a plurality of contact features that can engage such contact pads when the die is mounted thereon, to thereby provide electrical connections between the die and the shielded package 102.

As shown in FIGS. 7A and 7B, the example die 104 has thickness and lateral dimensions that are less than the depth and lateral dimensions of the pocket 112 in which it is mounted. Such a configuration allows the perimeter portion of the underside of the shielded package 102 to be mounted to a circuit board.

As further shown in FIGS. 7A and 7B, the perimeter portion of the underside of the shielded package 102 is shown to include a plurality of contact pads 204. Such contact pads can be configured to allow mounting of the shielded package 102 (with the die 104) to the circuit board, as well as facilitate various electrical connections between the shielded package 102 and the circuit board.

FIG. 8 shows a side sectional view of a layered packaging substrate 202 such as a laminate substrate. Such a laminate substrate can be utilized in some or all of the example shielded packages of FIGS. 3-5.

In the example of FIG. 8, the layered structure of the packaging substrate 202 is indicated as 245. Such layers can include various connection features such as conductive planes, conductive traces and conductive vias configured to provide various electrical functionalities and/or connections.

In some embodiments, some of such layers can be configured to define an underside pocket 204 such as the example pocket 112 of FIGS. 6 and 7. For example, each of one or more of the lower-most layers can include a pre-formed aperture such that when the layers are laminated, the aperture(s) form the underside pocket 204. In some embodiments, the underside pocket 204 can also be formed after lamination by, for example, milling operations.

In the example of FIG. 8, the ceiling of the underside pocket 204 is shown to include a plurality of contact features 246. Such contact features can be configured to allow mounting of the lower component (not shown in FIG. 8) and facilitate electrical connections between the lower component and the shielded package.

FIG. 9 shows a side sectional view of an example dual-sided package 100 that is similar to the example of FIG. 5, but showing additional example details in its packaging substrate (222) portion of the shielded package 220. More particularly, a conformal shield layer 174 that covers the upper surface of the overmold 172 and the four sides of the shielded package 220 is shown to be electrically connected to a grounding via through one or more conductive features 170 exposed on each side of the packaging substrate 222. Such conductive features are shown to be electrically connected to one or more conductive vias, which are in turn connected to a ground plane and grounding contact pads 247.

In some embodiments, the packaging substrate 222 that facilitates the foregoing conformal shielding functionality can be a laminate substrate or a ceramic substrate such as an LTCC substrate. As described in reference to FIG. 8, such a packaging substrate can include an underside pocket 224 dimensioned to receive a lower component 104, so as to yield a dual-sided package.

### Examples of Additional Features in Dual-Sided Packages

FIG. 10 shows that in some embodiments, an under-fill can be provided between a lower component and an underside of a shielded package to which the lower component is mounted. In FIG. 10, a dual-sided package 100 is similar to the pocket-based example of FIG. 2. An under-fill 230 is shown to be provided between a lower component 104 and the underside of a shielded package 102. Such an under-fill structure can provide a more secure mounting of the lower component 104.

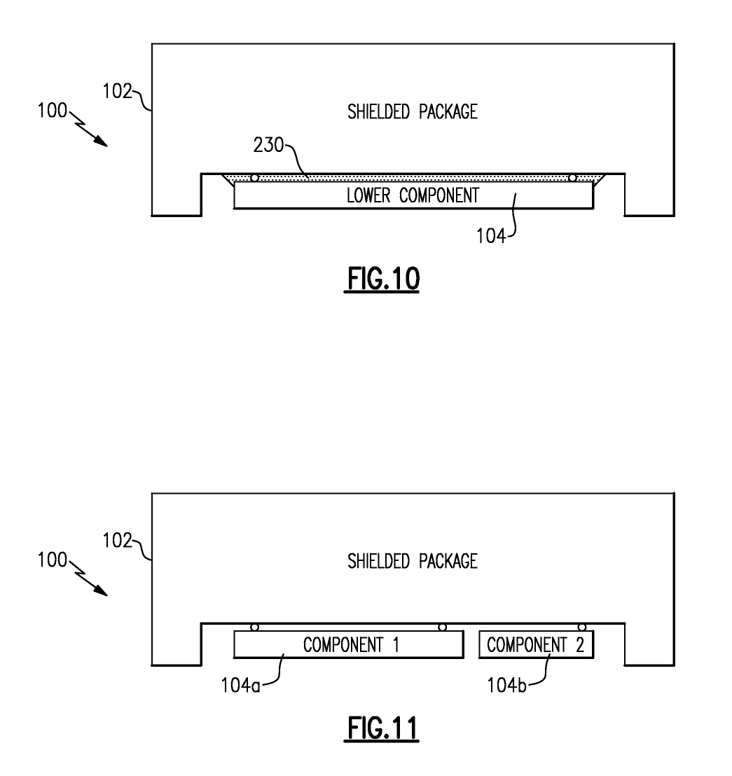

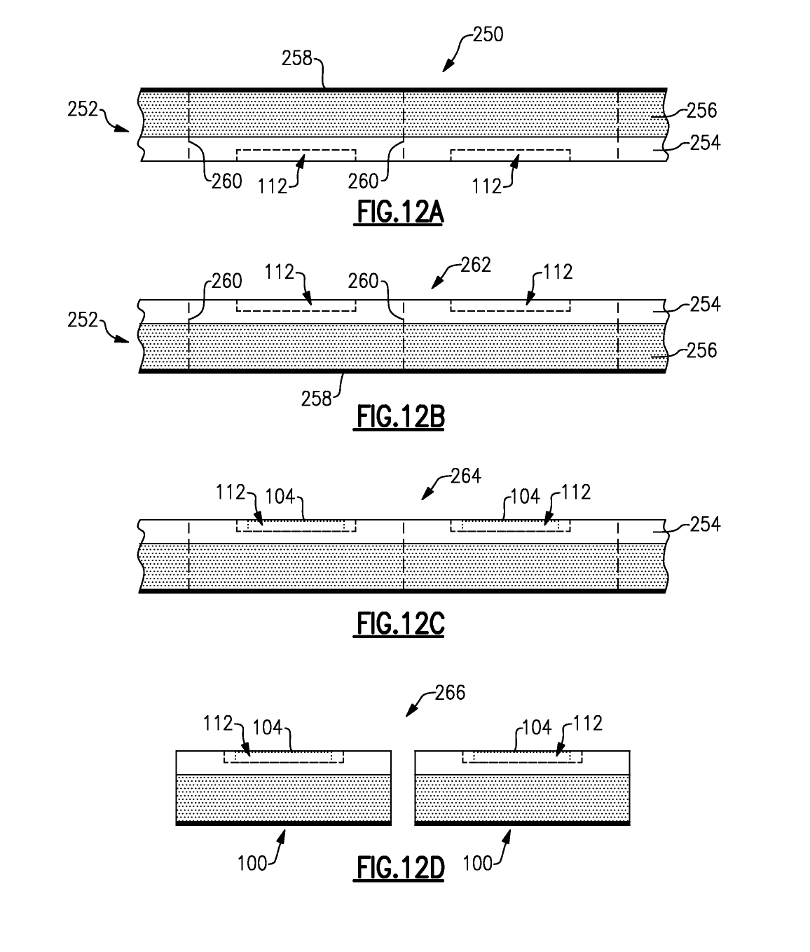

FIG. 11 shows that in some embodiments, a dual-sided package can include a plurality of lower components. In FIG. 11, a dual-sided package 100 is similar to the pocket-based example of FIG. 2. The dual-sided package 100 is shown to include two lower components 104a, 104b mounted to the underside of a shielded package 102.

Other additional features, variations, or any combination thereof, can be also be implemented.

### Examples Related to Fabrication of Dual-Sided Packages

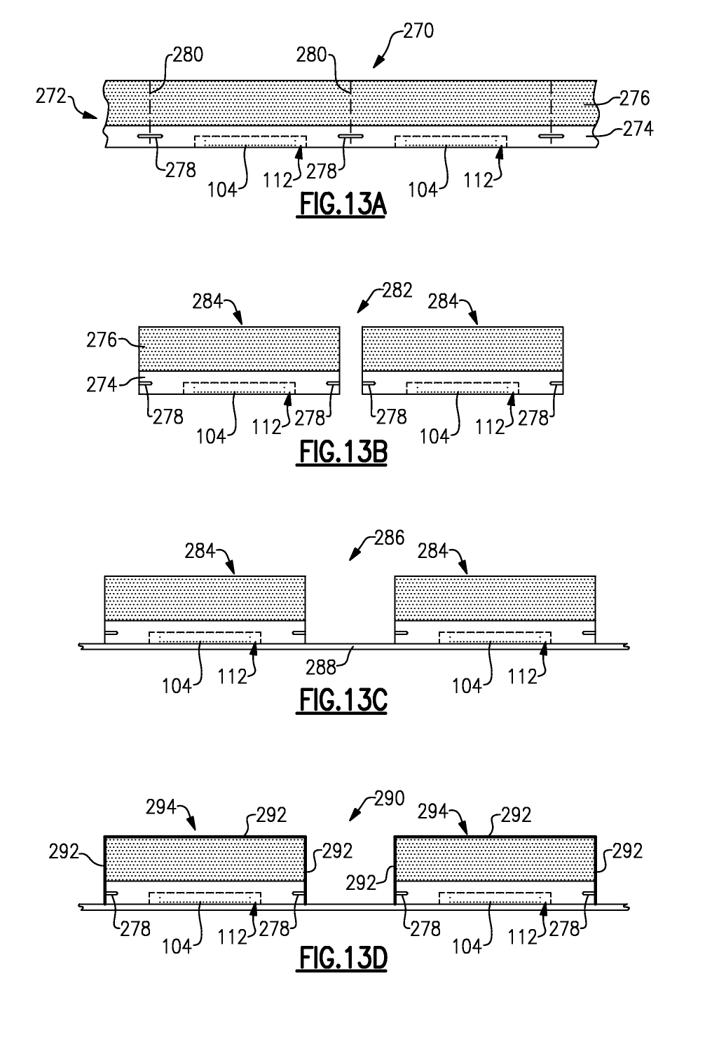

FIGS. 12 and 13 show examples of how dual-sided packages can be fabricated. As described herein, such examples can facilitate mass-production of dual-sided packages.

FIGS. 12A-12D show various stages of a fabrication process in which substantially all of dual-sided features can be implemented in a panel format having an array of to-be-separated units, before such units are separated (also referred to as singulated). Although described in the context of pocket-based dual-sided packages, it will be understood that one or more features of the fabrication technique of FIGS. 12A-12D can also be implemented for fabrication of other types of dual-sided packages. In some implementations, the fabrication process of FIGS. 12A-12D can be utilized for manufacturing of dual-sided packages described herein in reference to, for example, FIGS. 3 and 4.

FIGS. 13A-13D show various stages of a fabrication process in which a portion of the process is performed after individual units are singulated. Although described in the context of pocket-based dual-sided packages, it will be understood that one or more features of the fabrication technique of FIGS. 13A-13D can also be implemented for fabrication of other types of dual-sided packages. In some implementations, the fabrication process of FIGS. 13A-13D can be utilized for manufacturing of dual-sided packages described herein in reference to, for example, FIGS. 5 and 9.

Referring to FIG. 12A, a fabrication state 250 can include a panel 252 having a plurality of to-be-singulated units. For example, singulation can occur at boundaries depicted by dashed lines 260 so at to yield singulated individual units. The panel 252 is shown to include a substrate panel 254 on which upper portions (collectively indicated as 256) are formed. Each unit of such an upper-portion panel can include various parts described herein in reference to FIGS. 3 and 4. Such parts can include various components and shielding structures mounted or implemented on the substrate panel 254. The upper-portion panel 256 can also include an overmold layer which can be formed as a common layer for a number of individual units. Similar to the common overmold layer, an upper conductive layer 258 can be formed to cover a number of individual units. Each unit of the substrate panel 254 is depicted as including a pocket 112 on its underside as described herein in reference to, for example, FIGS. 3 and 4.

Referring to FIG. 12B, a fabrication state 262 can include the panel 252 of FIG. 12A being inverted so that its underside faces upward. Such an inverted orientation can allow processing of the underside while the individual units are still attached in the panel.

In the example states of FIGS. 12A and 12B, it is assumed that the pockets 112 on the underside of the substrate panel 254 are pre-formed. However, it will be understood that some of all of such pockets and related contact features can also be formed after the panel is inverted (e.g., as in FIG. 12B).

Referring to FIG. 12C, a fabrication state 264 can include a lower component 104 being attached for each unit on the underside (which is facing upward) of the substrate 254. Such a step is shown to yield an array of dual-sided units to be singulated.

Referring to FIG. 12D, a fabrication state 266 can include individual units being singulated to yield a plurality of dual-sided packages 100 substantially ready to be mounted to circuit boards. It will be understood that such a singulation process can be achieved while the panel (252) is in its inverted orientation (as shown in the example of FIG. 12D), or while the panel (252) is in its upright orientation (e.g., as in the example of FIG. 12A). After such a singulation process, each singulated dual-sided package 100 is depicted as including a lower component 104 mounted within an underside pocket 112.

As described herein, such processing of most or all of upper and lower sides of a substrate panel can be achieved since the side walls of the dual-sided packages are not utilized for shielding. However, when one or more side walls include shielding features, at least some of processing related to shielding need to be implemented with the corresponding side walls exposed. In some embodiments (e.g., where all four side walls include shielding features), at least some processing need to be performed on singulated units.

FIGS. 13A-13D show various states of a process that can be implemented to yield singulated units having some or all side walls with shielding features. Referring to FIG. 13A, a fabrication state 270 can include a panel 272 having a plurality of to-be-singulated units. For example, singulation can occur at boundaries depicted by dashed lines 280 so at to yield singulated individual units. The panel 272 is shown to include a substrate panel 274 on which upper portions (collectively indicated as 276) are formed. Each unit of such an upper-portion panel can include various parts described herein in reference to FIGS. 5 and 9. Such parts can include various components mounted or implemented on the substrate panel 274. The upper-portion panel 276 can also include an overmold layer which can be formed as a common layer for a number of individual units. Each unit of the substrate panel 274 is depicted as including a pocket 112 on its underside as described herein in reference to, for example, FIGS. 5 and 9.

In the example of FIG. 13A, a lower component 104 is shown to be mounted within each underside pocket 112. Such mounting of the lower component within the pocket 112 can be achieved by, for example, inverting the panel 272 so that the pockets 112 face upward (e.g., similar to the example stage of FIG. 12C). In some embodiments, the pockets 112 providing appropriately dimensioned spaces allows the lower components 104 to be mounted therein while the panel 272 remains un-singulated.

In the example of FIG. 13A, conductive features 278 are shown to be implemented within the substrate panel 274. Each conductive feature 278 can straddle the corresponding boundary 280, such than when separation occurs at the boundary 280, each of the two exposed side walls of the substrates includes an exposed portion of the conductive feature 278 that has been cut. Each of such cut conductive feature is electrically connect to a ground plane (not shown) within the corresponding substrate.

Referring to FIG. 13B, a fabrication state 282 can include a plurality of individual units 284 resulting from singulations along the boundary lines (280 in FIG. 13A). As described above, each of the individual units 284 includes side walls; and each side wall is shown to include an exposed portion of the cut conductive feature 278.

Referring to FIG. 13C, a fabrication state 286 can include the individual units 284 being positioned for formation of a conformal conductive layer. In some embodiments, the individual units 284 can be mounted on a tape 288 to be temporarily held in place during the formation of the conformal conductive layer. The individual units 284 can be positioned with sufficient spacing to allow effective formation of the conformal conductive layer on the side walls.

Referring to FIG. 13D, a fabrication state 290 can include formation of a conformal conductive layer 292 on the upper surface and the side surfaces of each of the individual units (284 in FIG. 13C) mounted on the tape 288. The conductive layer 292, in combination with the ground plane (connected through the conductive features 278) provides shielding functionality for a volume generally contained therein. In the example of FIG. 13D, each of the resulting individual units 294 can be the shielded package described in reference to FIGS. 5 and 9.

### Examples Related to Fabrication of Pocket-Based Dual-Sided Packages

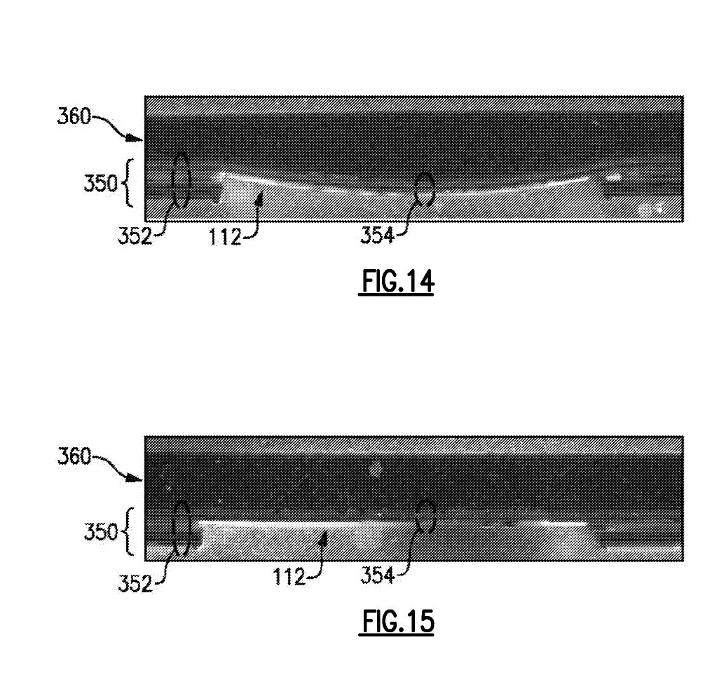

As described herein, pocket-based dual-sided packages can undergo some or all of fabrication steps while in a panel format. FIG. 14 shows an example of a mechanical problem that can arise during processing of the upper side of a substrate panel.

FIG. 14 is a photograph of a side sectional view of a partially completed panel that includes a substrate 350 and an overmold 360 formed on the substrate 350. The example substrate 350 is a laminate substrate with an underside pocket 112 as described herein. The region outside of the pocket 112 is shown to have a full set of layers, indicated as 352. The region inside of the pocket 112 is shown to have a reduced number of layers, indicated as 354.

When such a panel is positioned on a flat surface, the underside of the region 352 engages the flat surface, and the underside of the region 354 (inside the pocket 112) remains generally unsupported from the bottom. Accordingly, due to such lack of underside support for the region 354, application of pressure on the upper side of the substrate 350 can result in deformation of the region 354.

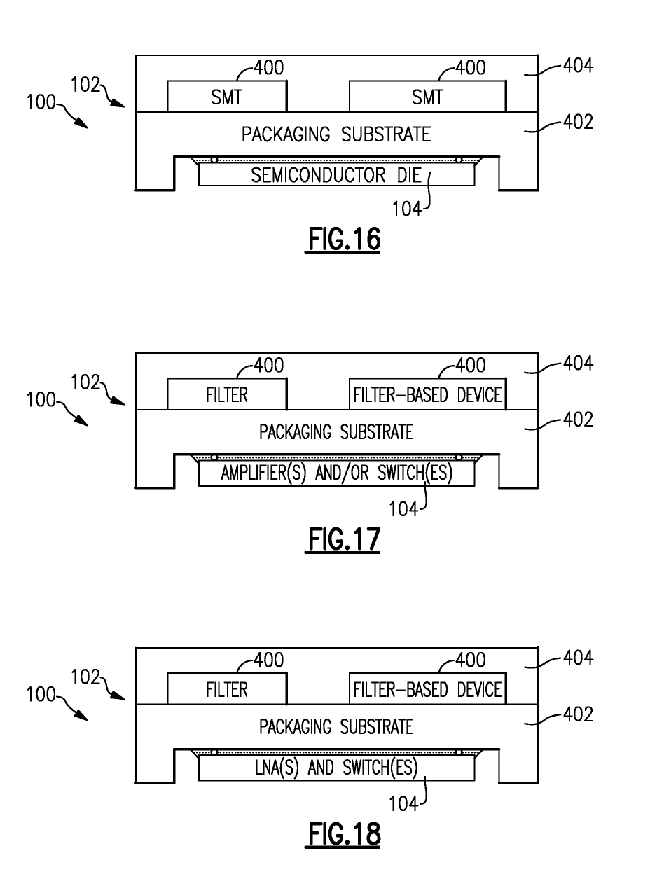

Formation of an overmold (such as the overmold 360 of FIG. 16) can provide such a pressure on the upper side of the substrate 350. Thus, in the example of FIG. 14, the region 354 is shown to be bowed downward due to the pressure of the overmold 360 and the lack of support underneath. The region 354 having a reduced thickness (e.g., due to the reduced number of layers) can also make such deformation more pronounced.

Such a deformation of the pocket 112 is problematic for a number of reasons. For example, such a deformation can result in mechanical damage (e.g., crack) to the substrate 350 (e.g., traces and vias in and/or around the region 354) and/or one or more components that are mounted above the substrate 350. In another example, the convex deformation of the ceiling of the pocket 112 can result in much of the space (of the pocket 112) being made un-usable for mounting of a component therein.

FIG. 15 is a photograph of a side sectional view of a partially completed panel that includes a substrate 350 similar to the example of FIG. 14. In FIG. 15, however, an overmold 360 formed on the substrate 350 does not deform the region 354, such that the integrity of the pocket 112 is preserved during the molding process. Such a desirable feature can be provided by implementing an underside support for the region 354 utilizing, for example, a support block having a pedestal that fits into the pocket 112. Additional details concerning such an underside support functionality can be found in, for example, U.S. patent application Ser. No. 14/809,239 filed on Jul. 26, 2015, entitled DEVICES AND METHODS RELATED TO SUPPORT FOR PACKAGING SUBSTRATE PANEL HAVING CAVITIES, which is also expressly incorporated by reference in its entirety for all purposes.

### Examples of Products Related to Dual-Sided Packages

As described herein, a shielded package and a lower component of a dual-sided package can include different combinations of components. FIG. 16 shows that in some embodiments, a dual-sided package 100 can include a shielded package 102 having one or more surface-mount technology (SMT) devices 400 mounted on a packaging substrate 402. As further shown in FIG. 16, one or more semiconductor die 104 can be mounted under the packaging substrate 402. As described herein, such one or more die can be mounted within a region generally defined by a pocket on the underside of the packaging substrate 402.

As further described herein, an overmold 404 can be formed over the packaging substrate 402 so as to substantially encapsulate the SMT device(s) 404, and to facilitate shielding functionalities. It will be understood that the shielded package 102 can include one or more shielding features as described herein.

FIG. 17 shows a dual-sided package 100 that can be a more specific example of the dual-sided package of FIG. 16. In the example of FIG. 17, the SMT device(s) can be one or more filters and/or filter-based devices 400 that are encapsulated by an overmold 404. Further, the semiconductor die mounted under a packaging substrate 402 can be a die having RF amplifier(s) and/or switch(es). Accordingly, such a dual-side package can be implemented as different modules configured to facilitate transmission and/or reception of RF signals. For example, the dual-sided package 100 can be implemented as a power amplifier (PA) module, a low-noise amplifier (LNA) module, a front-end module (FEM), a switching module, etc.

FIG. 18 shows a dual-sided package 100 that can be a more specific example of the dual-sided package of FIG. 17. In the example of FIG. 18, the semiconductor die mounted under a packaging substrate 402 can be a die having one or more LNAs and one or more switches. In some embodiments, such a dual-side package can be implemented as a module having LNA-related functionalities, including, for example, an LNA module.

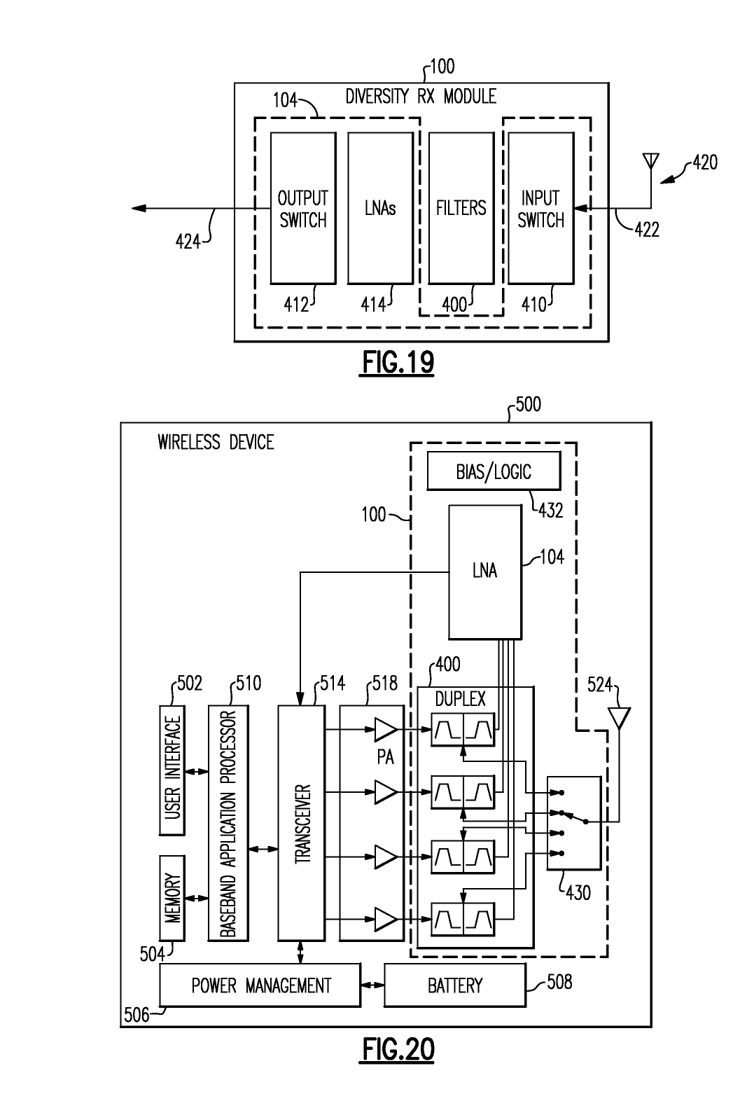

FIGS. 19 and 20 show examples of how the dual-sided package 100 of FIG. 18 can be implemented in wireless devices. FIG. 19 shows that in some embodiments, a dual-sided package having one or more features as described herein can be implemented as a diversity receive (RX) module 100. Such a module can be implemented relatively close to a diversity antenna 420 so as to minimize or reduce losses and/or noise in a signal path 422.

The diversity RX module 100 can be configured such that switches 410 and 412, as well as LNAs 414, are implemented in a semiconductor die (depicted as 104) that is mounted underneath a packaging substrate. Filters 400 can be mounted on such a packaging substrate as described herein.

As further shown in FIG. 19, RX signals processed by the diversity RX module 100 can be routed to a transceiver through a signal path 424. In wireless applications where the signal path 424 is relatively long and lossy, the foregoing implementation of the diversity RX module 100 close to the antenna 420 can provide a number of desirable features.

FIG. 20 shows that in some embodiment a dual-sided package having one or more features as described herein can be implemented in other types of LNA applications. For example, in an example wireless device 500 of FIG. 20, an LNA or LNA-related module 100 can be implemented as a dual-sided package as described herein, and such a module can be utilized with a main antenna 524.

The example LNA module 100 of FIG. 20 can include, for example, one or more LNAs 104, a bias/logic circuit 432, and a band-selection switch 430. Some or all of such circuits can be implemented in a semiconductor die that is mounted under a packaging substrate of the LNA module 100. In such an LNA module, some or all of duplexers 400 can be mounted on the packaging substrate so as to form a dual-sided package having one or more features as described herein.

FIG. 20 further depicts various features associated with the example wireless device 500. Although not specifically shown in FIG. 20, a diversity RX module 100 of FIG. 19 can be included in the wireless device 500 with the LNA module 100, in place of the LNA module 100, or any combination thereof. It will also be understood that a dual-sided package having one or more features as described herein can be implemented in the wireless device 500 as a non-LNA module.

In the example wireless device 500, a power amplifier (PA) circuit 518 having a plurality of PAs can provide an amplified RF signal to a switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

### General Comments

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged radio-frequency (RF) device comprising:
a packaging substrate configured to receive a plurality of components, the packaging substrate including a first side and a second side, the second side of the packaging substrate defining a pocket;
a shielded package implemented on the first side of the packaging substrate, the shielded package including an RF circuit, the shielded package configured to provide RF shielding for at least a portion of the RF circuit; and
a component mounted substantially within the pocket of the second side of the packaging substrate.

2. The device of claim 1 wherein the first and second sides of the packaging substrate correspond to upper and lower sides, respectively, when the packaged RF device is oriented to be mounted on a circuit board.

3. The device of claim 2 wherein the pocket includes a mounting surface configured to allow the component to be mounted thereon.

4. The device of claim 3 wherein the mounting surface of the pocket is substantially parallel to the upper surface of the packaging substrate.

5. The device of claim 4 wherein the mounting surface of the pocket include a plurality of contact features configured to provide mounting and electrical connection functionalities for the component mounted thereon.

6. The device of claim 3 wherein the pocket has a box shape, the box shape having a depth that is greater than the height of the component mounted therein.

7. The device of claim 3 wherein the packaging substrate includes a perimeter surface that partially or fully surrounds the pocket, the perimeter surface configured to allow the packaged RF device to be mounted on a circuit board.

8. (canceled)

9. The device of claim 2 wherein the packaging substrate includes a laminate substrate.

10. (canceled)

11. The device of claim 2 wherein the packaging substrate includes a ceramic substrate.

12. (canceled)

13. The device of claim 2 wherein the shielded package includes an overmold structure that substantially encapsulates the RF circuit.

14. The device of claim 13 wherein the shielded package further includes an upper conductive layer implemented on the overmold structure, the upper conductive layer electrically connected to a ground plane within the packaging substrate.

15. The device of claim 14 wherein the electrical connection between the upper conductive layer and the ground plane is achieved through one or more conductors within the overmold structure.

16. The device of claim 15 wherein the one or more conductors include shielding wirebonds arranged relative to the RF circuit to provide RF shielding functionality for at least a portion of the RF circuit.

17. The device of claim 15 wherein the one or more conductors include one or more SMT devices mounted on the packaging substrate, the one or more SMT devices arranged relative to the RF circuit to provide RF shielding functionality for at least a portion of the RF circuit.

18. The device of claim 14 wherein the electrical connection between the upper conductive layer and the ground plane is achieved through a conformal conductive coating implemented on one or more sides of the overmold structure.

19. The device of claim 18 wherein the conformal conductive coating extends to corresponding one or more sides of the packaging substrate.

20. The device of claim 19 wherein the packaging substrate includes one or more conductive features each having a portion exposed at the corresponding side of the packaging substrate to form an electrical connection with the conformal conductive coating, each conductive feature further connected to the conductive plane within the substrate packaging.

21-22. (canceled)

23. The device of claim 2 wherein the component includes an SMT device.

24-27. (canceled)

28. A method for manufacturing packaged radio-frequency (RF) devices, the method comprising:
providing or forming a packaging substrate configured to receive a plurality of components, the packaging substrate including a first side and a second side, the second side of the packaging substrate defining a pocket;
forming a shielded package on the first side of the packaging substrate, the shielded package including an RF circuit, the shielded package configured to provide RF shielding for at least a portion of the RF circuit; and
mounting a component substantially within the pocket of the second side of the packaging substrate.

29. A wireless device comprising:
a circuit board configured to receive a plurality of packaged modules; and
a shielded radio-frequency (RF) module mounted on the circuit board, the RF module including a packaging substrate configured to receive a plurality of components, the packaging substrate including a first side and a second side, the second side of the packaging substrate defining a pocket , the RF module further including a shielded package implemented on the first side of the packaging substrate, the shielded package including an RF circuit, the shielded package configured to provide RF shielding for at least a portion of the RF circuit, the RF module further including a component mounted substantially within the pocket of the second side of the packaging substrate.
